(19) United States
(12) Patent Application Publication
(10) Pub. No.: US 2021/0242839 A1
(43) Pub. Date: Aug. 5, 2021

(54) MULTI-CHIP MODULE OF RADIO FREQUENCY POWER AMPLIFIER

(71) Applicant: INNOGRATION (SUZHOU) CO., LTD., Suzhou (CN)

(72) Inventors: Yong ZHANG, Suzhou (CN); Yinghao ZHUO, Suzhou (CN); Gordon Chiang MA, Phoenix, AZ (US)

(21) Appl. No.: 16/972,565

(22) PCT Filed: Jul. 9, 2019
(86) PCT No.: PCT/CN2019/095206

§ 371 Date: Dec. 4, 2020

(30) Foreign Application Priority Data
Jul. 10, 2018 (CN) 201810752764.4

(51) Int. Cl. H03F 3/195; H03F 1/56; H03F 3/24

(52) U.S. Cl. CPC H03F 3/195; H03F 1/56; H03F 2200/222; H03F 2200/451; H03F 3/245

(57) ABSTRACT

A multichip module of a radio frequency power amplifier includes an active transistor and a matching coupling circuit. The active transistor and matching coupling circuit are integrated in a single package carrier; the matching coupling circuit, obtained by an integrated passive device process, is used for impedance matching and signal coupling and has a coupling output connected to the second pin of the package carrier to serve as an interface for sampling coupling signals of an external circuit, and a through input connected to the output of the active transistor; the matching coupling circuit matches the optimal impedance of the active transistor to Z1; the output impedance Z1 of the through output of the matching coupling circuit is variable; the through output of the matching coupling circuit is connected to the input of a circulator; and the input impedance of the circulator is Z0, which is conjugated with Z1.

This application claims the priority benefit of China Patent Application No. 201810752764.4 filed on Jul. 10, 2018, and entitled “Multi-chip module of radio frequency power amplifier” which is incorporated by reference in its entirety.

### TECHNICAL FIELD

The present invention relates to a radio frequency (RF) power amplifier, in particular to multi-chip module of a radio frequency power amplifier.

### BACKGROUND

An RF power amplifier is a key component of the transmitter end in a communication base station system. With the increasingly fierce competition in the communications market, new requirements have been put forward for the power amplifier as a key component, such as high integration, miniaturization and high efficiency.

The traditional power amplifier module separates the transistor amplifier, coupler and circulator by means of separation; cascading modules in a discrete form has the characteristics of low integration and large occupation area. The traditional power amplifier module uses the standard 50 Ohm as the output impedance of the power amplifier, the input and output impedance of the coupler, and the input impedance of the circulator, which limits the flexibility of the design or increases the matching area, not conducive to the miniaturization of the module.

### SUMMARY

In view of the above-mentioned technical problems, the purpose of the present invention is to provide a multichip module of an RF (radio frequency) power amplifier, which is small in size and easy to be packaged and integrated.

In order to solve these problems in the prior art, the present invention provides the following technical solution:

A multichip module of a radio frequency power amplifier is provided, wherein: an active transistor and a matching coupling circuit are integrated in a single package carrier; the matching coupling circuit, obtained by an integrated passive device process, is used for impedance matching and signal coupling; the matching coupling circuit has a coupling output connected to the second pin of the package carrier to serve as an interface for sampling coupling signals of an external circuit, and a through input connected to the output of the active transistor; the matching coupling circuit matches the optimal impedance of the active transistor to Z1; the output impedance Z1 of the through output of the matching coupling circuit is variable; the through output of the matching coupling circuit is connected to the input of a circulator; and the input impedance of the circulator is Z0, which is conjugated with Z1.

In a preferred technical solution, the circulator, integrated in a single package carrier, has a through port connected to a third pin of the package carrier, and an isolation port connected to a fourth pin of the package carrier.

In a preferred technical solution, when the optimal impedance of the active transistor is much less than 50 Ohm, the value of Z1 is less than 50 Ohm; and when the optimal impedance of the active transistor is much greater than 50 Ohm, the value of Z1 is greater than 50 Ohm.

A filter and an antenna are directly connected after the circulator to form a complete transmission link.

Compared with the solutions in the prior art, the present invention has the following advantages:

The present invention can integrate the active transistor, the matching coupling circuit and the circulator in a single package, which is small in size, and easy to be packaged and integrated.

### BRIEF DESCRIPTION OF DRAWINGS

The present invention will be further described below with reference to drawings and examples.

FIG. 1 shows a multichip module of a radio frequency power amplifier according to an example of the present invention; and

FIG. 2 shows a multichip module of a radio frequency power amplifier according to another example of the present invention.

### DETAILED DESCRIPTION OF PREFERRED EMBODIMENTS

The above solution will be further described below in conjunction with specific examples. It should be understood that these examples are used to illustrate the present invention and not limited to limiting the scope of the present invention. The implementation conditions used in the examples can be further adjusted according to the conditions provided by specific manufacturers; and the implementation conditions not specified are usually conditions in routine experiments.

### EXAMPLE 1

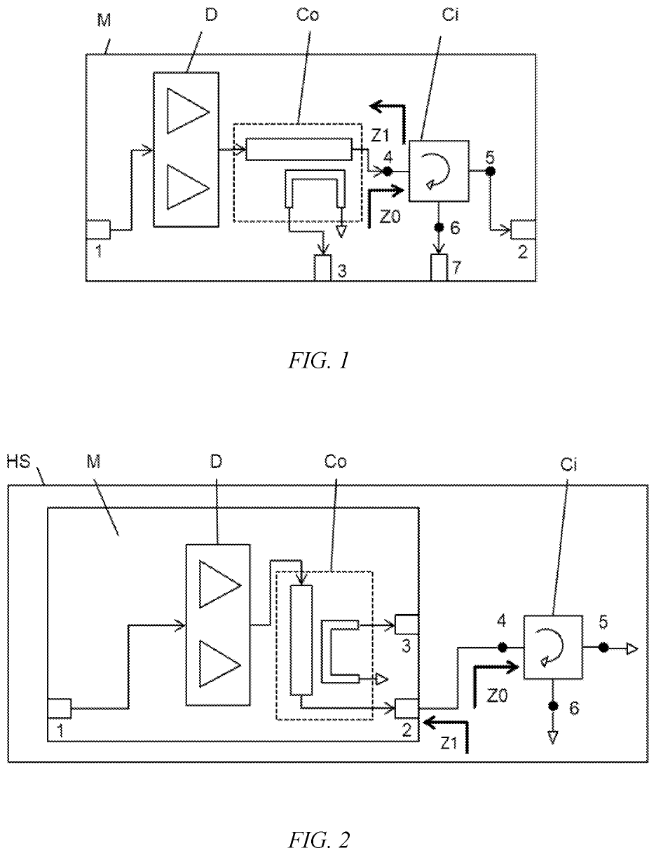

FIG. 1 shows an RF power amplifier multichip module, wherein: the matching coupling circuit Co is achieved in the form of an IPD (integrated passive device), and has the functions of impedance matching and signal coupling; the active transistor D, the matching coupling circuit Co and the circulator Ci are integrated in a single package M, and the pin 1 of the package is internally connected to the left input part of the active transistor D; and the signal is amplified by the active transistor D, and then transmitted from the right output to the matching coupling circuit Co.

As a part of the output matching of the active transistor D, the matching coupling circuit Co matches the optimal impedance of the active transistor D to Z1, with the output impedance of the through output of the matching coupling circuit Co designed as Z1.

Z1 can be selected to be less than 50 Ohm or greater than 50 Ohm. When the optimal impedance of the active transistor is much less than 50 Ohm, the value of Z1 is less than 50 Ohm; and when the optimal impedance of the active transistor is much greater than 50 Ohm, the value of Z1 is greater than 50 Ohm.

The coupling terminal of the matching coupling circuit Co is internally connected to a pin 3 of the package. The signal is outputted through the through output of the matching coupling circuit Co, and then enters the input 4 of the circulator Ci. The input impedance of the circulator Ci is Z0, which is conjugated with Z1. The output 5 of the circulator Ci is connected to the package pin 2, and the signal is outputted through the two ports. The isolation port 6 of the circulator Ci is connected to the package pin 7.

### EXAMPLE 2

The matching coupling circuit Co and the transistor amplifier D can also be integrated in one package, and the circulator Ci can be separately externally mounted on the same heat sink base HS, as shown in FIG. 2. This can also reduce the volume.

A filter and an antenna can be directly connected after the circulator to form a complete transmission link. The filter and antenna can be integrated in the package, or installed separately.

The above embodiments of the present invention are merely used to illustratively describe or explain the principle of the present invention, and do not constitute a limitation of the present invention. Therefore, any modifications, equivalent substitutions, improvements, etc., which are made without departing from the spirit and scope of the present invention, are intended to be included within the scope of the present invention. Besides, the appended claims of the present invention are intended to cover all the changes and modifications falling within the scope and boundary, or equivalents thereof, of the appended claims.

1. A multichip module of a radio frequency power amplifier, comprising:
an active transistor and a matching coupling circuit,
wherein the active transistor and the matching coupling circuit are integrated in a single package carrier; the matching coupling circuit, obtained by an integrated passive device process, is used for impedance matching and signal coupling; the matching coupling circuit has a coupling output connected to the second pin of the package carrier to serve as an interface for sampling coupling signals of an external circuit, and a through input connected to the output of the active transistor; the matching coupling circuit matches the optimal impedance of the active transistor to Z1; the output impedance Z1 of the through output of the matching coupling circuit is variable; the through output of the matching coupling circuit is connected to the input of a circulator; and the input impedance of the circulator is Z0, which is conjugated with Z1.

2. The multichip module of a radio frequency power amplifier according to claim 1, wherein: the circulator, integrated in a single package carrier, has a through port connected to a third pin of the package carrier, and an isolation port connected to a fourth pin of the package carrier.

3. The multichip module of a radio frequency power amplifier according to claim 1, wherein: when the optimal impedance of the active transistor is much less than 50 Ohm, the value of Z1 is less than 50 Ohm; and when the optimal impedance of the active transistor is much greater than 50 Ohm, the value of Z1 is greater than 50 Ohm.

4. The multichip module of a radio frequency power amplifier according to claim 1 further comprising:
a filter and an antenna,
wherein the filter and the antenna are directly connected after the circulator to form a complete transmission link.
